(19) United States
(12) Patent Application Publication
(10) Pub. No.: US 2006/0196849 A1
(43) Pub. Date: Sep. 7, 2006

(54) Composition and method for polishing a sapphire surface

(76) Inventors: Kevin Moeggenborg, Naperville, IL (US); Isaac Cherian, Aurora, IL (US); Mukesh Desai, Naperville, IL (US)

Correspondence Address: STEVEN WESEMAN;ASSOCIATE GENERAL COUNSEL, I.P., CABOT MICROELECTRONICS CORPORATION, 870 NORTH COMMONS DRIVE, AURORA, IL, 60504, US

(21) Appl. No.: 11/365,155

(22) Filed: Mar. 1, 2006

Related U.S. Application Data
(60) Provisional application No. 60/658,653, filed on Mar. 4, 2005.

(51) Int. Cl. C03C 15/00; H01L 21/461; B44C 1/22

(52) U.S. Cl. 216/88; 216/89; 438/692

(57) ABSTRACT

An improved composition and method for polishing a sapphire surface is disclosed. The method comprises abrading a sapphire surface, such as a C-plane or R-plane surface of a sapphire wafer, with a polishing slurry comprising an abrasive amount of an inorganic abrasive material such as colloidal silica suspended in an aqueous medium having a salt compound dissolved therein. The aqueous medium has a basic pH and includes the salt compound in an amount sufficient to enhance the sapphire removal rate relative to the rate achievable under the same polishing conditions using a the same inorganic abrasive in the absence of the salt compound.

### CROSS-REFERENCE TO RELATED APPLICATIONS

This application claims the benefit of U.S. Provisional Application for Patent Ser. No. 60/658,653, filed on Mar. 4, 2005, which is incorporated herein by reference.

### FIELD OF THE INVENTION

The invention relates to improved compositions and methods for polishing sapphire surfaces. More particularly, the invention relates to methods for enhancing the sapphire removal efficiency of abrasive materials such as colloidal silica in a sapphire polishing process by adding a salt compound to the slurry.

### BACKGROUND OF THE INVENTION

Silica abrasive materials are commonly utilized in chemical mechanical polishing of metals, metal oxides, silicon materials. In such applications, abrasive silica particles are suspended in a liquid medium, such as water, sometimes with the aid of a surfactant as a dispersing agent. Choi et al. Journal of the Electrochemical Society, 151 (3) G185-G189 (2004) have reported that addition of sodium chloride, lithium chloride and potassium chloride to suspensions of silica in a basic aqueous medium can enhance the removal rate of silicon dioxide when added to the suspension at levels in the range of about 0.01 to about 0.1 molar. Choi et al. have also reported that removal rates begin to drop back to control levels as the salt concentration is increased beyond 0.1 molar to 1 molar for sodium and lithium salts, and that surface roughness increases for each of the salts as the salt concentration approaches 1 molar, as does the depth of surface damage.

Sapphire is a generic term for alumina (A₂O₃) single-crystal materials. Sapphire is a particularly useful material for use as windows for infrared and microwave systems, optical transmission windows for ultraviolet to near infrared light, light emitting diodes, ruby lasers, laser diodes, support materials for microelectronic integrated circuit applications and growth of superconducting compounds and gallium nitride, and the like. Sapphire has excellent chemical stability, optical transparency and desirable mechanical properties, such as chip resistance, durability, scratch resistance, radiation resistance, a good match for the coefficient of thermal expansion of gallium arsenide, and flexural strength at elevated temperatures.

Sapphire wafers are commonly cut along a number of crystallographic axes, such as the C-plane (0001 orientation, also called the 0-degree plane or the basal plane), the A-plane (11-20 orientation, also referred to as 90 degree sapphire) and the R-plane (1-102 orientation, 57.6 degrees from the C-plane). R-plane sapphire, which is particularly preferred for silicon-on-sapphire materials used in semiconductor, microwave and pressure transducer application, is about 4 times more resistant to polishing than C-plane sapphire, which is typically used in optical systems, infrared detectors, and growth of gallium nitride for light-emitting diode applications.

The polishing and cutting of sapphire wafers is an extremely slow and laborious process. Often, aggressive abrasives, such as diamond must be used to achieve acceptable polishing rates. Such aggressive abrasive materials can impart serious surface damage and contamination to the wafer surface. Typical sapphire polishing involves continuously applying a slurry of abrasive to the surface of the sapphire wafer to be polished, and simultaneously polishing the resulting abrasive-coated surface with a rotating polishing pad, which is moved across the surface of the wafer, and which is held against the wafer surface by a constant down-force, typically in the range of about 5 to 20 pounds per square inch (psi). Due to the aggressive nature of diamond abrasives, and the typically slow polishing rates achievable with other abrasive materials, there is an ongoing need for methods to enhance the efficiency of sapphire polishing with conventional, less aggressive abrasives, such as colloidal silica. The methods of the present invention fulfill this need.

### BRIEF SUMMARY OF THE INVENTION

The present invention provides an improved composition and method for polishing a sapphire surface. The method comprises abrading a sapphire surface, such as a C-plane or R-plane surface of a sapphire wafer, with a polishing slurry comprising an abrasive amount of an inorganic abrasive material, such as colloidal silica, suspended in an aqueous medium. The aqueous medium has a basic pH and includes a dissolved salt compound, as an additive, in an amount sufficient to enhance the sapphire removal rate relative to the rate achievable under the same polishing conditions using the same amount of the same inorganic abrasive material in the absence of the salt compound. The salt compound preferably is an alkali metal salt and/or alkaline earth metal salt of a mineral acid, an organic acid, or a combination thereof.

Non-limiting examples of preferred salt compounds include alkali metal and alkaline earth metal salts of an acid, such as a mineral acid or an organic acid. Sodium chloride is a particularly preferred salt compound.

A preferred method of polishing a sapphire surface comprises applying a polishing slurry to a surface of a sapphire wafer mounted in a rotating carrier and abrading the sapphire surface with a rotating polishing pad while maintaining at least a portion of the polishing slurry disposed between the polishing surface of the pad and the surface of the sapphire wafer. The polishing slurry comprises an abrasive amount of an inorganic abrasive material suspended in an aqueous medium having a pH preferably of at least about 9 and including a sapphire removal rate-enhancing amount of a salt compound dissolved therein. The polishing pad has a planar polishing surface that rotates about an axis of rotation perpendicular to the sapphire surface at a selected rotation rate. The rotating polishing surface of the pad is pressed against the sapphire surface with a selected level of down-force perpendicular to the sapphire surface.

The combined action of the rotating polishing pad and polishing slurry removes sapphire from the sapphire surface at a removal rate greater than the sapphire removal rate achievable by abrading the sapphire surface with the same pad, at the same rate of rotation, and the same down-force, utilizing a polishing slurry containing the substantially the same amount of the same inorganic abrasive material, absent the salt compound. Preferably, the polishing slurry is applied to the sapphire surface by continuously supplying the slurry onto the sapphire surface while the rotating polishing pad is urged against the sapphire surface.

### DETAILED DESCRIPTION OF THE INVENTION

An improved process for polishing a sapphire surface comprises abrading the surface, with a polishing slurry comprising an abrasive amount of an inorganic abrasive material suspended in an aqueous medium having a basic pH, preferably a pH of at least about 9, more preferably about 10 to about 11. The aqueous medium includes a dissolved salt compound that enhances the sapphire removal rate relative to the removal rate obtainable by a slurry containing substantially the same concentration of the same abrasive material, but absent the salt compound, when evaluated under substantially the same polishing conditions (e.g., substantially the same temperature, down-pressure, polishing pad, pad rotation rate, carrier rotation rate, and abrasive concentration). The salt compound is present in an amount sufficient to enhance the removal rate, preferably by at least about 45 percent relative to the rate obtained using a polishing slurry that does not contain the salt compound. Preferably, the salt compound is present in the slurry in an amount in the range of about 0.1 to about 1.5 percent by weight, more preferably about 0.2 to about 1 percent by weight, based on the weight of the slurry.

Non-limiting examples of suitable inorganic abrasive materials for use in the methods of the present invention include alumina, colloidal silica, and fumed silica abrasive materials. Preferably, the inorganic abrasive material is a silica material, more preferably colloidal silica. The abrasive material preferably has a mean particle size in the range of about 20 to about 200, more preferably 50 to about 150. Preferably, the inorganic abrasive material is suspended in an aqueous medium at a concentration in the range of about 1 to about 50 percent by weight, more preferably about 20 to about 40 percent by weight. One or more surfactants, such as a cationic surfactant, an anionic surfactant, or a mixture of a nonionic surfactant with either a cationic or anionic surfactant, can be used to maintain the inorganic abrasive material in suspension in the aqueous medium. Preferably, the slurry of inorganic abrasive material is substantially free of surfactants.

Non-limiting examples of suitable colloidal silica materials useful in the methods of the present invention include the BINDZIL® brand colloidal silica slurries marketed by EKA Chemicals division of Akzo Nobel, such as BINDZIL® CJ2-0 (about 40 weight percent silica, about 110 nm mean particle size), colloidal silica materials marketed by Nalco Chemical Company, such as TX 11005 (about 30 weight percent by weight silica, about 50 nm mean particle size), and the like. The concentration of the colloidal silica can be adjusted to the desired level (e.g., about 20 to about 40 percent solids) by dilution with deionized water, if necessary.

Preferred salt compounds include alkali metal and alkaline earth metal salts of an acid, such as a mineral acid or an organic acid. Preferred mineral acids include hydrochloric acid, hydrobromic acid, hydroiodic acid, sulfuric acid, and nitric acid. Preferred organic acids include ascorbic acid, oxalic acid and picolinic acid. Preferred alkali metal salts include lithium, sodium, and potassium salts, more preferably sodium and lithium salts. Preferred alkaline earth metal salts include calcium and magnesium salts, more preferably calcium salts. Other preferred salt compounds are iron salts and aluminum salts. Preferred iron and aluminum salts include iron halides (e.g., ferric chloride) and aluminum halides (e.g., aluminum chloride) which when added to a basic aqueous medium such generate iron hydroxides (e.g., ferric hydroxide) and aluminum hydroxides, respectively. Examples of preferred salt compounds include, without limitation lithium chloride, sodium chloride, sodium bromide, sodium iodide, sodium sulfate, calcium chloride, ferric chloride, and mixtures thereof. Sodium chloride is a particularly preferred salt compound.

The methods of the present invention and provide material removal rates for polishing sapphire surfaces significantly higher than removal rates achievable with conventional abrasive slurries in the absence of the salt compound.

The methods of the present invention are particularly useful for polishing or planarizing a C-plane or R-plane surface of a sapphire wafer and provide material removal rates for polishing sapphire surfaces significantly higher that removal rates achieved with conventional abrasive slurries in the absence of the salt compound. Removal rates that are at least about 45 percent higher, preferably at least about 60 percent higher, more preferably at least about 70 percent higher than the removal rate, obtainable with a substantially similar slurry, absent the salt compound, are readily achieved under substantially the same polishing conditions.

The methods of the present invention can be carried out utilizing any abrasive polishing equipment. Preferably, the polishing is accomplished with sapphire wafers mounted in a rotating carrier, using a rotating polishing pad applied to the surface of the wafers at a selected down-force, preferably with a down-force in the range of about 2 to about 20 psi at a pad rotation rate in the range of about 20 to about 150 revolutions per minute (rpm), with the wafers mounted on a carrier rotating at about 20 to about 150 rpm. Suitable polishing equipment is commercially available from a variety of sources, such as Logitech Ltd, Glasgow, Scotland, UK and SpeedFam-IPEC Corp., Chandler, Ariz., as is well known in the art.

The following non-limiting examples are provided to illustrate preferred embodiments of the methods of the present invention.

### EXAMPLE 1

C-plane sapphire wafers (about 2 inches diameter) were polished for about 10 minutes on a Logitech CDP polisher. The wafers were mounted on the carrier, which was rotating at a carrier speed of about 65 rpm. A 22.5 inch diameter A100 polishing pad rotating at a platen speed of about 69 rpm was utilized at an applied down-force of about 11.5 psi. The pad was conditioned with about 150 sweeps of deionized water, with 50 sweeps of deionized water between each polishing run.

A 20 percent by weight slurry of colloidal silica (BINDZIL® CJ2-0, 110 nm mean particle size), adjusted to about pH 10 (i.e., by addition of sodium hydroxide) was applied to the wafers at a slurry feed rate of about 160 milliliters per minute (ml/min). A salt compound (calcium chloride or sodium chloride) was added to the silica slurry as a removal-rate-enhancing additive. Without the additive, sapphire removal rates in the range of about 250 to about 400 Angstroms per minute (Å/min) were obtained. Addition of 0.1 percent by weight of calcium chloride (on a slurry weight basis, about 0.11 molar concentration of CaCl₂ in the aqueous phase) increased the removal rate to about 530 Å/min compared to 250 Å/min for the control with no added salt compound.

Addition of about 0.1 percent by weight of sodium chloride to the slurry (on a slurry weight basis; about 0.22 molar NaCl concentration in the aqueous phase) afforded a sapphire removal rate of about 580 Å/min compared to about 390 Å/min for the control with no salt. Increasing the sodium chloride content to about 0.2 percent by weight (about 0.44 molar) afforded a removal rate of 690 Å/min. Increasing the sodium chloride level further, to about 0.5 percent by weight, and 0.7 percent by weight did not increase the removal rate any further. Addition of about 1 percent by weight (slurry weight basis) of sodium chloride afforded a further increase in removal rate to about 740 Å/min. As the results indicate, sodium chloride added to the slurry of colloidal silica at a concentration in the range of about 0.2 percent to about 1 percent by weight (slurry weight basis) surprisingly provided an overall increase in sapphire removal rate of about 75 percent compared to the control with no additive under the same polishing conditions. Similarly, 0.1 percent by weight of calcium chloride added to the slurry surprisingly increased the removal rate by about 100 percent. The variability in the observed removal rates for the controls is likely due to variations in the surface quality of the wafers prior to polishing.

Similar evaluations of C-plane polishing were performed at slurry pH values of about 3 and about 7, using the same colloidal silica abrasive slurry, with and without 1 percent by weight of added sodium chloride. A decrease in removal rate was observed at these pH values, down to about 200 Å/min with NaCl, compared about 300 Å/min with no additive. These results indicate that a basic pH is important to the sapphire removal rate enhancing effect of the salt compound additives when used in conjunction with colloidal silica abrasives.

### EXAMPLE 2

R-plane sapphire wafers (about 4 inches diameter) were polished for about 10 minutes on a, IPEC 472 polisher. The wafers were mounted on the carrier, which was rotating at a carrier speed of about 57 rpm. A 22.5 inch diameter A100 polishing pad rotating at a platen speed of about 63 rpm was utilized at a down-force of about 16 psi. A 20 percent by weight slurry of colloidal silica (BINDZIL® CJ2-0, 110 nm mean particle size), adjusted to about pH 10 with sodium hydroxide, was applied to the wafers at a slurry feed rate of about 200 milliliters per minute (ml/min). The pad was conditioned with about 150 sweeps of deionized water, with 50 sweeps of deionized water between each polishing run.

About 1 percent of a salt compound (sodium chloride) was added to the silica slurry; a control comparison utilized about 0.5 percent by weight of DEQUEST® 2010 (about 60 percent by weight 1-hydroxy ethylidene-1,1-diphosphonic acid in water, available from Solutia Inc.) in place of the sodium chloride. The control removal rate was about 160 Å/min, whereas the removal rate in the presence of the salt compound was about 608 Å/min.

Another run utilized a control slurry comprising about 0.5 percent by weight of DEQUEST® 2010 and about 2% hydrogen peroxide, compared to a slurry containing about 1 percent by weight of sodium chloride and 2 percent by weight hydrogen peroxide. The control afforded a removal rate of about 170 Å/min, whereas addition of the salt compound afforded a removal rate of about 304 Å/min.

Another evaluation was performed under the same polishing conditions (i.e., A100 pad, platen speed of about 63 rpm, carrier speed of about 57 rpm, down-force of about 16 psi, slurry feed of about 200 ml/min), in four replicate runs. The control slurry (BINDZIL® CJ2-0) afforded sapphire removal rates in the range of about 310 to about 340 Å/min in four repeat runs. The removal rates with 1 percent by weight added sodium chloride (slurry weight basis) afforded about 450 to about 630 Å/min removal rates in four repeat runs. Again, a surprising enhancement in the sapphire removal rate of about 45 to about 85 percent was observed utilizing the method of the invention compared to the convention silica slurry alone.

### EXAMPLE 3

C-plane sapphire wafers (about 2 inches diameter) were polished for about 10 minutes on a Logitech CDP polisher. The wafers were mounted on the carrier, which was rotating at a carrier speed of about 65 rpm. A 22.5 inch diameter A100 polishing pad rotating at a platen speed of about 69 rpm was utilized at a down-force of about 11.5 psi. A 20 percent by weight slurry of colloidal silica (BINDZIL® CJ2-0, 110 nm mean particle size), adjusted to about pH 10 (using sodium hydroxide, except for runs in which potassium chloride was used as an additive, in which case potassium hydroxide was used), was applied to the wafers at a slurry feed rate of about 200 milliliters per minute (ml/min). The pad was conditioned with about 150 sweeps of deionized water, with 50 sweeps of deionized water between each polishing run.

A salt compound (sodium chloride, potassium chloride, sodium bromide, sodium iodide, sodium ascorbate, or sodium sulfate) was added to the silica slurry as a removal-rate-enhancing additive. Without the salt compound additive, sapphire removal rates in the range of about 450 to about 590 Å/min were obtained. Addition of 1 percent by weight of sodium chloride (on a slurry weight basis) increased the removal rate to about 880 Å/min; addition of 1 percent by weight of potassium chloride (on a slurry weight basis) increased the removal rate to about 740 Å/min; addition of 1 percent by weight of sodium bromide (on a slurry weight basis) increased the removal rate to about 870 Å/min; addition of 1 percent by weight of sodium iodide (on a slurry weight basis) increased the removal rate to about 790 Å/min; addition of 1 percent by weight of sodium ascorbate (on a slurry weight basis) increased the removal rate to about 720 Å/min; and addition of 1 percent by weight of potassium chloride (on a slurry weight basis) increased the removal rate to about 920 Å/min.

Similar results were obtained with sodium oxalate (about 1 percent by weight), ferric chloride (about 0.1 percent by weight added to the basic slurry to form ferric hydroxide), aluminum chloride (about 0.1 percent by weight added to the basic slurry to form aluminum hydroxide), sodium picolinate (about 0.1 percent by weight), and lithium chloride (about 1 percent by weight).

The data from the Examples show that the methods of the present invention provide unexpectedly improved removal rates compared to the sapphire removal rate obtained with the same abrasive slurry composition, but in the absence of the salt compound. Similar enhancements were obtained with colloidal silica having a mean particle size of about 50 nm (Nalco TX11005) as well as slurries having concentrations of colloidal silica in the range of about 5 to about 40 percent by weight. In addition, atomic force microscopy of sapphire wafers polished by the methods of the invention using a 40 percent by weight colloidal silica abrasive having a mean particle size of about 110 nm suspended in deionized water adjusted to a pH of about 10 and including about 1 percent by weight sodium chloride dissolved in the deionized water, exhibited low surface roughness (i.e., roughness values in the range of about 0.2 to about 0.4 nm, which were just above the noise level of the measurements). The observed removal rate enhancements of at least about 45 percent, and often greater than 70 percent, for the methods of the present invention are significantly and surprisingly higher than would be expected due to ionic strength effects, such as those reported by Choi et al. for polishing of a silicon dioxide surface with abrasive silica slurries. These results are particularly unexpected in light of the significantly harder nature of a sapphire surface relative to a silicon dioxide surface and the low surface roughness observed for the polished wafers. The methods of the present invention afford an elegant solution to the lengthy polishing times required for polishing sapphire surfaces, such as sapphire C-plane and R-plane surfaces.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as” or “fore example”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A method of polishing a sapphire surface comprising abrading a sapphire surface with a polishing slurry comprising an abrasive amount of an inorganic abrasive material suspended in an aqueous medium having a basic pH and including a sapphire removal rate-enhancing amount of a salt compound dissolved in the aqueous medium.

2. The method of claim 1 wherein the inorganic abrasive material comprises about 1 to about 50 percent by weight of the polishing slurry.

3. The method of claim 1 wherein the inorganic abrasive material has a mean particle size in the range of about 20 to about 200 nm.

4. The method of claim 1 wherein the inorganic abrasive material has a mean particle size in the range of about 50 to about 150 nm.

5. The method of claim 1 wherein the inorganic abrasive material is a colloidal silica.

6. The method of claim 1 wherein the aqueous medium has a pH of at least about 9.

7. The method of claim 1 wherein the aqueous medium has a pH in the range of about 10 to about 11.

8. The method of claim 1 wherein the salt compound is an alkali metal or alkaline earth metal salt of an acid.

9. The method of claim 8 wherein the alkali metal salt is a sodium salt or a lithium salt.

10. The method of claim 8 wherein the alkaline earth metal salt is a calcium salt.

11. The method of claim 8 wherein the acid is a mineral acid.

12. The method of claim 11 wherein the mineral acid is selected from the group consisting of hydrochloric acid, hydrobromic acid, hydroiodic acid, sulfuric acid, and nitric acid.

13. The method of claim 8 wherein the acid is an organic acid.

14. The method of claim 13 wherein the organic acid is ascorbic acid, oxalic acid, picolinic acid, or a mixture thereof.

15. The method of claim 1 wherein the salt compound is an iron salt.

16. The method of claim 1 wherein the salt compound is an aluminum salt.

17. The method of claim 1 wherein the salt compound is selected from the group consisting of lithium chloride, sodium chloride, sodium bromide, sodium iodide, sodium sulfate, calcium chloride, ferric hydroxide, and a mixture thereof.

18. The method of claim 1 wherein the sapphire removal rate-enhancing amount of the salt compound is an amount sufficient to increase the rate of sapphire removal by at least about 45 percent compared to the rate of sapphire removal obtained utilizing a polishing slurry of containing the same concentration of the same abrasive material absent the salt compound, utilized under the same polishing conditions.

19. The method of claim 1 wherein the removal rate-enhancing amount is about 0.1 to about 1.5 percent by weight of the salt compound based on the total weight of the slurry.

20. The method of claim 1 wherein the sapphire surface is a sapphire C-plane surface.

21. The method of claim 1 wherein the sapphire surface is a sapphire R-plane surface.

22. A method of polishing a sapphire surface comprising abrading a surface of a sapphire wafer mounted on a rotating carrier with a rotating polishing pad and a polishing slurry, the polishing slurry comprising an abrasive amount of a silica material suspended in an aqueous medium having a pH of at least about 9 and including a sapphire removal rate-enhancing amount of a salt compound dissolved therein, the polishing surface of the pad being pressed against the surface of the sapphire wafer at a selected down-force with at least a portion of the polishing slurry disposed between the polishing surface of the pad and the surface of the sapphire wafer.

23. The method of claim 22 wherein the salt compound is an alkali metal or alkaline earth metal salt of a mineral acid.

24. The method of claim 22 wherein the salt compound is an alkali metal or alkaline earth metal salt of an organic acid.

25. The method of claim 22 wherein the silica material is colloidal silica.

26. The method of claim 22 wherein the silica material has a mean particle size in the range of about 20 to about 200 nm.

27. The method of claim 22 wherein the salt compound is an alkali metal or alkaline earth metal salt of an acid.

28. The method of claim 22 wherein the slurry is substantially free of surfactant.

29. The method of claim 22 wherein the removal rate-enhancing amount is about 0.1 to about 1.5 percent by weight of the salt compound based on the total weight of the slurry.

30. A method of polishing a sapphire surface comprising:
(a) applying a polishing slurry to a surface of a sapphire wafer mounted in a rotating carrier, the polishing slurry comprising about 1 to about 50 percent by weight of an abrasive colloidal silica suspended in an aqueous medium having a pH in the range of about 10 to about 11 and including a sapphire removal rate-enhancing amount of an alkali metal or alkaline earth metal salt of a mineral acid dissolved therein; and
(b) abrading the surface of the wafer with a polishing pad having a planar polishing surface rotating at a selected rotation rate about an axis perpendicular to the surface of the wafer, the polishing surface of the pad being pressed against the surface of the wafer with a selected level of down-force perpendicular to the surface of the wafer, with at least a portion of the polishing slurry disposed between the polishing surface of the pad and the surface of the sapphire wafer, the rotating pad removing sapphire from the surface of the wafer at a removal rate at least about 45 percent greater than the sapphire removal rate achievable by abrading the sapphire surface with the same pad, at the same pad rotation rate, the same carrier rotation rate, and the same perpendicular down-force utilizing a polishing slurry containing the same amount of the same colloidal silica in the absence of the alkali metal or alkaline earth metal salt of an acid.

31. The method of claim 30 wherein the colloidal silica is present in the slurry at a concentration in the range of about 20 to about 40 percent by weight.

32. The method of claim 30 wherein the salt compound is an alkali metal or alkaline earth metal salt of an acid selected from the group consisting of an organic acid, a mineral acid, and a combination thereof.

33. A sapphire polishing slurry comprising an abrasive amount of a colloidal silica suspended in an aqueous carrier and a sapphire removal-rate-enhancing amount of salt compound dissolved therein.

34. The polishing slurry of claim 33 wherein the salt compound is an alkali metal salt.

35. The polishing slurry of claim 33 wherein the alkali metal salt is sodium chloride.

36. The polishing slurry of claim 33 wherein the colloidal silica is present in the slurry at a concentration in the range of about 20 to about 40 percent by weight.
